(19) United States
(12) Patent Application Publication
(10) Pub. No.: US 2017/0301854 A1
(43) Pub. Date: Oct. 19, 2017

(54) POLYMERIC PIEZOELECTRIC FILM

(71) Applicant: Mitsui Chemicals, Inc., Minato-ku, Tokyo (JP)

(72) Inventors: Katsutoshi OZAKI, Nagoya-shi, Aichi (JP); Kazuhiro TANIMOTO, Nagoya-shi, Aichi (JP); Keisuke SATO, Koga-shi, Ibaraki (JP); Masaki AMANO, Nagoya-shi, Aichi (JP)

(73) Assignee: Mitsui Chemicals, Inc., Minato-ku, Tokyo (JP)

(21) Appl. No.: 15/516,930

(22) PCT Filed: Oct. 20, 2015
(86) PCT No.: PCT/JP2015/079591

§ 371 Date: Apr. 5, 2017

(30) Foreign Application Priority Data
Oct. 27, 2014 (JP) 2014-218539

(51) Int. Cl. H01L 41/18; C08J 5/18; B29C 55/12; B29K 67/00

(52) U.S. Cl. CPC H01L 41/18; C08J 5/18; B29C 55/12; B29K 2067/046; C08J 2367/04; B29K 2995/0003

(57) ABSTRACT

Provided is a polymeric piezoelectric film including a helical chiral polymer having a weight average molecular weight of from 50,000 to 1,000,000 and having optical activity, in which a crystallinity of the film measured by a DSC method is from 20% to 80%, a product of a standardized molecular orientation MORc measured by a microwave transmission-type molecular orientation meter based on a reference thickness of 50 μm and the crystallinity is from 40 to 700, and, when a refractive index in a slow axis direction in the film surface is nₓ, a refractive index in a fast axis direction in the film surface is n_{y}, a refractive index in a thickness direction of the film is n_{z}, and an Nz coefficient=(nₓ−n_{z})/(nₓ−n_{y}), the Nz coefficient is from 1.108 to 1.140.

### TECHNICAL FIELD

The present invention relates to a polymeric piezoelectric film.

### BACKGROUND ART

PZT (PbZrO₃—PbTiO₃ solid solution) which is a ceramic material is conventionally used for a piezoelectric material in many cases. Since PZT contains lead, however, a polymeric piezoelectric material (polymeric piezoelectric film) whose environmental load is low and which is flexible is currently increasingly used as a piezoelectric material.

Examples of a currently known polymeric piezoelectric material include a Pauling-type polymer represented by nylon 11, polyvinyl fluoride, polyvinyl chloride, polyurea, polyvinylidene fluoride (β-type) (PVDF), or vinylidene fluoride-trifluoro ethylene copolymer (P(VDF-TrFE)) (75/25).

In recent years, use of an optically active polymer, such as polypeptide or polylactic acid, has drawn attention in addition to the above polymeric piezoelectric materials. A polylactic acid polymer is known to exhibit piezoelectricity by a simple mechanical stretching operation.

Among optically active polymers, the piezoelectricity of a polymer crystal, such as polylactic acid, results from permanent dipoles of C═O bonds existing in the screw axis direction. Especially, polylactic acid, in which the volume fraction of side chains with respect to a main chain is small and the content of permanent dipoles per volume is large, is said to constitute an ideal polymer among polymers having helical chirality. Polylactic acid exhibiting piezoelectricity only by a stretching treatment does not require a poling treatment and is known to maintain the piezoelectric modulus without decrease for several years.

Since polylactic acid exhibits a variety of piezoelectric properties as described above, a variety of polymeric piezoelectric materials using polylactic acid have been reported. For example, a polymeric piezoelectric material obtained by stretching a sheet formed by an aliphatic polyester composition mainly in a uniaxial direction has been disclosed (for example, see Document 1). A technique in which an unstretched film using polylactic acid is biaxially stretched to form a transversely stretched film (biaxially stretched film) has also been disclosed (see, for example, Documents 2 and 3).

Document 1 Japanese Patent Application Laid-Open (JP-A) No. 2014-086703

Document 2 JP-A No. 2011-243606

Document 3 JP-A No. 2012-153023

### SUMMARY OF INVENTION

### Technical Problem

Incidentally, in order for a polymeric piezoelectric film to exhibit piezoelectricity, molecular chains need to be oriented in one direction. For example, in the case of a longitudinal uniaxially stretched film described in Document 1, since the stretching direction (the direction in which a molecular chain is oriented) is in the MD (Machine Direction) direction, the film is easily to be torn in a direction parallel to the MD direction, and has a drawback in that the tear strength in a certain direction is low. The tear strength in a certain direction is hereinafter also referred to as “longitudinal tear strength”.

Meanwhile, by using biaxial stretching equipment, it is possible to stretch a film in both the MD direction and a TD (Transverse Direction) direction perpendicular to the MD direction. For example, the above Documents 2 and 3 describe a technique relating to a transversely stretched film obtained by stretching mainly in the TD direction during biaxially stretching. A transversely stretched film is more advantageous from the viewpoint of film production capacity since a wide film can be manufactured easily as compared with a longitudinal uniaxially stretched film.

However, in the case of a transversely stretched film, the longitudinal tear strength in the TD direction is low, and the film is torn easily in a direction parallel to the TD direction. In a continuous production process of a film, a tension is generated in the MD direction, so that a break of the film in the TD direction is likely to occur in a production step, and a continuous production thereof for a long time is difficult. Production stop due to such a break in the TD direction, which does not occur during the production of a longitudinal uniaxially stretched film, is a big problem in producing a transversely stretched film.

In order to obtain a film with high longitudinal tear strength, generally, it is preferable to form a film by increasing the longitudinal ratio and the lateral ratio. When the longitudinal ratio and the lateral ratio are brought close to the same degree, the orientation of the molecular chain decreases, and the piezoelectricity decreases.

Meanwhile, the present inventors intensively studied to find, by adjusting the longitudinal stretching ratio and the transverse stretching ratio, ranges in which the modulus of elasticity, the yield stress and the like in a direction at 45° with respect to the stretching direction (MD direction) are increased while maintaining the piezoelectricity, and substantial sensor sensitivity when a polymeric piezoelectric film is used for a piezoelectric sensor device or the like is improved.

In view of the above, an object of the invention is to provide a polymeric piezoelectric film which can maintain high sensor sensitivity when used for a device, has high longitudinal tear strength, and is excellent in productivity.

### Solution to Problem

Specific measures to attain the object are as follows.

<1> A polymeric piezoelectric film comprising a helical chiral polymer having a weight average molecular weight of from 50,000 to 1,000,000 and having optical activity,

wherein: a crystallinity of the film measured by a DSC method is from 20% to 80%, a product of the crystallinity and a standardized molecular orientation MORc measured by a microwave transmission-type molecular orientation meter based on a reference thickness of 50 μm is from 40 to 700, and when a refractive index in a slow axis direction in the film surface is nₓ, a refractive index in a fast axis direction in the film surface is n_{y}, a refractive index in a thickness direction of the film is n_{z}, and an Nz coefficient=(nₓ−n_{z})/(nₓ−n_{y}), the Nz coefficient is from 1.108 to 1.140.

<2> The polymeric piezoelectric film according to <1>, wherein an internal haze with respect to visible light is 40% or less, and a piezoelectric constant d₁₄ measured by a stress-electric charge method at 25° C. is 1 pC/N or more.

<3> The polymeric piezoelectric film according to <1> or <2>, wherein an internal haze with respect to visible light is 20% or less.

<4> The polymeric piezoelectric film according to any one of <1> to <3>, wherein the helical chiral polymer is a polymer having a main chain comprising a repeating unit represented by the following formula (1):

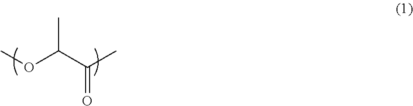

<5> The polymeric piezoelectric film according to any one of <1> to <4>, wherein an optical purity of the helical chiral polymer is 95.00% ee or more.

<6> The polymeric piezoelectric film according to any one of <1> to <5>, wherein a content of the helical chiral polymer is 80% by mass or more.

<7> The polymeric piezoelectric film according to any one of <1> to <6>, wherein the refractive index nₓ in the slow axis direction in the film surface is from 1.4720 to 1.4740.

<8> The polymeric piezoelectric film according to any one of <1> to <7>, wherein a piezoelectric constant measured by a stress-electric charge method is 6 pC/N or more.

<9> The polymeric piezoelectric film according to any one of <1> to <8>, wherein the Nz coefficient is from 1.109 to 1.130.

<10> The polymeric piezoelectric film according to any one of <1> to <9>, wherein an internal haze with respect to visible light is 1% or less.

<11> The polymeric piezoelectric film according to any one of <1> to <10>, wherein the film is a biaxially stretched film, and wherein, when a stretching ratio in a direction in which the stretching ratio is large is defined as a main stretching ratio, and a stretching ratio in a direction which is perpendicular to the direction in which the stretching ratio is large and which is parallel to the film surface is defined as a secondary stretching ratio, a main stretching ratio/secondary stretching ratio is from 3.0 to 3.5.

<12> The polymeric piezoelectric film according to <11>, wherein a product of the main stretching ratio and the secondary stretching ratio is from 4.6 to 5.6.

### Advantageous Effects of Invention

According to the present invention, a polymeric piezoelectric film which can maintain high sensor sensitivity when used for a device, has high longitudinal tear strength, and is excellent in productivity can be provided.

### BRIEF DESCRIPTION OF DRAWING

FIG. 1 is a graph illustrating the relationship between Nz coefficient and d₁₄×E×σ in Examples 1 and 2 and Comparative Examples 1 and 2.

### DESCRIPTION OF EMBODIMENTS

Here, a numerical range represented by “from A to B” means a range including numerical values A and B as a lower limit value and an upper limit value, respectively.

Here, a film surface means a principal plane of a film. Here, the term “principal plane” refers to a plane having the largest area among the surfaces of the polymeric piezoelectric film. The polymeric piezoelectric film of the present embodiment may have two or more principal planes. For example, when the polymeric piezoelectric film has two plates A with a size of 10 mm×0.3 mm, two plates B with a size of 3 mm×0.3 mm, and two plates C with a size of 10 mm×3 mm, the principal plane of the polymeric piezoelectric film is the plate C, and the film has two principal planes.

<Polymeric Piezoelectric Film>

A polymeric piezoelectric film of the invention is a polymeric piezoelectric film comprising a helical chiral polymer having a weight average molecular weight of from 50,000 to 1,000,000 and having optical activity, wherein: a crystallinity of the film measured by a DSC method is from 20% to 80%, a product of the crystallinity and a standardized molecular orientation MORc measured by a microwave transmission-type molecular orientation meter based on a reference thickness of 50 μm is from 40 to 700, and when a refractive index in a slow axis direction in the film surface is nₓ, a refractive index in a fast axis direction in the film surface is n_{y}, a refractive index in a thickness direction of the film is n_{z}, and an Nz coefficient=(nₓ−n_{z})/(nₓ−n_{y}), the Nz coefficient is from 1.108 to 1.140.

When a piezoelectric material has the above configuration, a polymeric piezoelectric film which can maintain high sensor sensitivity when used for a device, has high longitudinal tear strength, and is excellent in productivity can be obtained.

More particularly, when the Nz coefficient is from 1.108 to 1.140, a polymer film in which parameters related to sensor sensitivity evaluated by, for example, a piezoelectric constant d₁₄, modulus of elasticity, and yield stress can be maintained high, and which can be suitably used for a variety of sensors can be provided. Further, since a polymer film of the invention has excellent longitudinal tear strength, a break during production can be suppressed, and therefore, the polymer film has excellent productivity.

That the tear strength in a certain direction deteriorates is occasionally expressed herein as “longitudinal tear strength deteriorates”, and a situation where the tear strength in a certain direction is low, is occasionally expressed herein as “longitudinal tear strength is low”.

Further, that a phenomenon of deterioration of the tear strength in a certain direction is suppressed, is occasionally expressed herein as “longitudinal tear strength is improved”, and a situation where the phenomenon of deterioration of the tear strength in a certain direction is suppressed, is occasionally expressed as “longitudinal tear strength is high” or “superior in longitudinal tear strength”.

[Optically Active Helical Chiral Polymer]

An optically active helical chiral polymer refers to a polymer having a helical molecular structure and having optical activity.

Hereinafter, a helical chiral polymer with the weight average molecular weight from 50,000 to 1,000,000 having optical activity is also referred to as an “optically active polymer”.

Examples of the optically active polymer include polypeptide, cellulose, a cellulose derivative, a polylactic acid-type resin, polypropylene oxide, and poly(β-hydroxybutyric acid). Examples of the polypeptide include poly(γ-benzyl glutarate), and poly(γ-methyl glutarate). Examples of the cellulose derivative include cellulose acetate, and cyanoethyl cellulose.

The optical purity of the optically active polymer is preferably 95.00% ee or more, more preferably 97.00% ee or more, further preferably 99.00% ee or more, and particularly preferably 99.99% ee or more from a viewpoint of enhancing the piezoelectricity of a polymeric piezoelectric film. Desirably, the optical purity of the optically active polymer is 100.00% ee. It is presumed that, by selecting the optical purity of the optically active polymer in the above range, packing of a polymer crystal exhibiting piezoelectricity becomes denser and as the result the piezoelectricity is improved.

The optical purity of the optically active polymer in the current embodiment is a value calculated according to the following formula:

Optical purity (% ee)=100×|L-form amount−D-form amount|/(L-form amount+D-form amount);

That is, the optical purity of the optically active polymer is a value obtained by multiplying (multiplying) ‘the value obtained by dividing (dividing) “the amount difference (absolute value) between the amount [% by mass] of optically active polymer in L-form and the amount [% by mass] of optically active polymer in D-form” by “the total amount of the amount [% by mass] of optically active polymer in L-form and the amount [% by mass] of optically active polymer in D-form’” by ‘100’.

In this regard, for the L-form amount [% by mass] of the optically active polymer and the D-form amount [% by mass] of the optically active polymer, values to be obtained by a method using high performance liquid chromatography (HPLC) are used. Specific particulars with respect to a measurement will be described below.

Among the above optically active polymers, a polymer having a main chain comprising a repeating unit represented by the following formula (1) is preferable from a viewpoint of enhancement of the optical purity and improving the piezoelectricity.

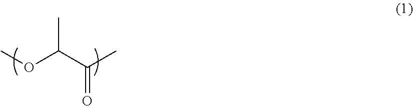

Examples of a compound with the main chain containing a repeating unit represented by the formula (1) include a polylactic acid resin. Among others, polylactic acid is preferable, and a homopolymer of L-lactic acid (PLLA) or a homopolymer of D-lactic acid (PDLA) is most preferable.

The polylactic acid-type resin means “polylactic acid”, a “copolymer of one of L-lactic acid or D-lactic acid, and a copolymerizable multi-functional compound”, or a mixture of the two. The “polylactic acid” is a polymer linking lactic acid by polymerization through ester bonds into a long chain, and it is known that polylactic acid can be produced by a lactide process via a lactide, a direct polymerization process, by which lactic acid is heated in a solvent under a reduced pressure for polymerizing while removing water, or the like. Examples of the “poly(lactic acid)” include a homopolymer of L-lactic acid, a homopolymer of D-lactic acid, a block copolymer including a polymer of at least one of L-lactic acid and D-lactic acid, and a graft copolymer including a polymer of at least one of L-lactic acid and D-lactic acid.

Examples of the “copolymerizable multi-functional compound” include a hydroxycarboxylic acid, such as glycolic acid, dimethylglycolic acid, 3-hydroxybutyric acid, 4-hydroxybutyric acid, 2-hydroxypropanoic acid, 3-hydroxypropanoic acid, 2-hydroxyvaleric acid, 3-hydroxyvaleric acid, 4-hydroxyvaleric acid, 5-hydroxyvaleric acid, 2-hydroxycaproic acid, 3-hydroxycaproic acid, 4-hydroxycaproic acid, 5-hydroxycaproic acid, 6-hydroxycaproic acid, 6-hydroxymethylcaproic acid, and mandelic acid; a cyclic ester, such as glycolide, β-methyl-δ-valerolactone, γ-valerolactone, and ε-caprolactone; a polycarboxylic acid, such as oxalic acid, malonic acid, succinic acid, glutaric acid, adipic acid, pimelic acid, azelaic acid, sebacic acid, undecanedioic acid, dodecanedioic acid, and terephthalic acid, and an anhydride thereof; a polyhydric alcohol, such as ethylene glycol, diethylene glycol, triethylene glycol, 1,2-propanediol, 1,3-propanediol, 1,3-butanediol, 1,4-butanediol, 2,3-butanediol, 1,5-pentanediol, 1,6-hexanediol, 1,9-nonanediol, 3-methyl-1,5-pentanediol, neopentylglycol, tetramethylene glycol, and 1,4-hexanedimethanol; a polysaccharide such as cellulose; and an aminocarboxylic acid such as α-amino acid.

Examples of the above “copolymerizable polyfunctional compound” include a compound described in paragraph 0028 of WO 2013/054918.

Examples of the “copolymer of one of L-lactic acid or D-lactic acid, and a copolymerizable polyfunctional compound” include a block copolymer or a graft copolymer having a polylactic acid sequence, which can form a helical crystal.

The concentration of a structure derived from a copolymer component in the optically active polymer is preferably 20 mol % or less. For example, when the optically active polymer is a polylactic acid-type polymer, with respect to the total number of moles of a structure derived from lactic acid and a structure derived from a compound copolymerizable with lactic acid (copolymer component) in the polylactic acid-type polymer, the copolymer component is preferably 20 mol % or less.

The optically active polymer (for example, polylactic acid-type resin) can be produced, for example, by a method of obtaining the polymer by direct dehydration condensation of lactic acid, as described in JP-A No. S59-096123 and JP-A No. H7-033861, or a method of obtaining the same by a ring-opening polymerization of lactide, which is a cyclic dimer of lactic acid, as described in U.S. Pat. No. 2,668,182 and No. 4,057,357.

In order to make the optical purity of the optically active polymer (for example, polylactic acid-type resin) obtained by any of the production processes to 95.00% ee or more, for example, when a polylactic acid is produced by a lactide process, it is preferable to polymerize lactide, whose optical purity has been enhanced to 95.00% ee or more by a crystallization operation.

[Weight Average Molecular Weight of Optically Active Polymer]

The weight average molecular weight (Mw) of the optically active polymer according to the current embodiment is from 50,000 to 1,000,000. When the lower limit of the weight average molecular weight of the optically active polymer is 50,000 or more, the mechanical strength of a molding from the optically active polymer improves. The lower limit of the weight average molecular weight of the optically active polymer is preferably 100,000 or more, and more preferably 150,000 or more. Meanwhile, when the upper limit of the weight average molecular weight of the optically active polymer is 1,000,000 or less, moldability when a polymeric piezoelectric film is obtained by molding (for example, extrusion molding) improves.

The upper limit of the weight average molecular weight is preferably 800,000 or less, and more preferably 300,000 or less.

The molecular weight distribution (Mw/Mn) of the optically active polymer is preferably from 1.1 to 5, more preferably from 1.2 to 4, and further preferably from 1.4 to 3, from a viewpoint of the strength of a polymeric piezoelectric film. The weight average molecular weight Mw and the molecular weight distribution (Mw/Mn) of a polylactic acid polymer are measured using a gel permeation chromatograph (GPC) by the following GPC measuring method.

—GCPC Measuring Apparatus—

GPC-100 manufactured by Waters Corp.

### —Column—

SHODEX LF-804 manufactured by Showa Denko K.K.

### —Preparation of Sample—

A polylactic acid-type polymer is dissolved in a solvent (e.g. chloroform) at 40° C. to prepare a sample solution with the concentration of 1 mg/mL.

### —Measurement Condition—

A sample solution 0.1 mL is introduced into the column at a temperature of 40° C. and a flow rate of 1 mL/min by using a solvent [chloroform].

The sample concentration in a sample solution separated by the column is measured by a differential refractometer. Based on polystyrene standard samples, a universal calibration curve is created and the weight average molecular weight (Mw) and the molecular weight distribution (Mw/Mn) of a polylactic acid polymer are calculated.

For a polylactic acid-type polymer, a commercial polylactic acid may be used, and examples thereof include PURASORB (PD, PL) manufactured by Purac Corporate, LACEA (H-100, H-400) manufactured by Mitsui Chemicals, Inc., and Ingeor™ biopolymer manufactured by NatureWorks LLC.

When a polylactic acid-type resin is used as the optically active polymer and in order to make the weight average molecular weight (Mw) of the polylactic acid resin 50,000 or more, it is preferable to produce the optically active polymer by a lactide process, or a direct polymerization process.

A polymeric piezoelectric film of the current embodiment may contain only one kind of the optically active polymer, or may contain two or more kinds thereof.

Although there is no particular restriction on a content (if two or more kinds are used, the total content; hereinafter holds the same) of the optically active polymer (helical chiral polymer) in a polymeric piezoelectric film of the current embodiment, 80% by mass or more with respect to the total mass of the polymeric piezoelectric film is preferable.

When the content is 80% by mass or more, the piezoelectric constant tends to improve.

(Stabilizer)

A polymeric piezoelectric film according to the present embodiment may contain, as a stabilizer, a compound which has one or more functional groups selected from the group consisting of a carbodiimide group, an epoxy group, and an isocyanate group and whose weight average molecular weight is from 200 to 60,000.

By this, a hydrolysis reaction of an optically active polymer (helical chiral polymer) is suppressed, thereby further improving the moist heat resistance of a film to be obtained.

Regarding a stabilizer, description in paragraphs 0039 to 0055 of WO 2013/054918 can be appropriately referred to.

(Antioxidant)

A polymeric piezoelectric film according to the present embodiment may contain an antioxidant. The antioxidant is at least one selected from the group consisting of a hindered phenol-based compound, a hindered amine-based compound, a phosphite-based compound, and a thioether-based compound.

For the antioxidant, a hindered phenol-based compound or a hindered amine-based compound is preferably used. By this, a polymeric piezoelectric film having excellent moist heat resistance and transparency can be provided.

(Other Components)

A polymeric piezoelectric film of the embodiment may contain, to the extent that the advantage of the invention be not compromised, known resins, as represented by polyvinylidene fluoride, a polyethylene resin and a polystyrene resin, inorganic fillers, such as silica, hydroxyapatite, and montmorillonite, publicly known crystal nucleating agents such as phthalocyanine, and other components.

When a polymeric piezoelectric film contains a component other than a helical chiral polymer, the content of the component other than a helical chiral polymer with respect to the total mass of polymer piezoelectric film is preferably 20% by mass or less, and more preferably 10% by mass or less.

To the extent that the advantage of the current embodiment is not compromised, a polymeric piezoelectric film of the present embodiment may contain a helical chiral polymer other than the afore-described optically active polymer (namely, a helical chiral polymer having a weight average molecular weight (Mw) from 50,000 to 1,000,000 and having optical activity).

—Inorganic Filler—

A polymeric piezoelectric film of the current embodiment may contain at least one kind of inorganic filler.

For example, in order to form a polymeric piezoelectric film to a transparent film inhibiting generation of a void such as an air bubble, an inorganic filler such as hydroxyapatite may be dispersed into a polymeric piezoelectric film in a nano-state. However for dispersing the inorganic filler into a nano-state, large energy is required to disintegrate an aggregate, and if the inorganic filler is not dispersed in a nano-state the film transparency may occasionally be compromised. Therefore, if a polymeric piezoelectric film according to the current embodiment contains an inorganic filler, the content of the inorganic filler with respect to the total mass of the polymeric piezoelectric film is preferably less than 1% by mass.

Further, if a polymeric piezoelectric film contains components other than the optically active polymer, the content of the components other than the optically active polymer is preferably 20% by mass or less, and more preferably 10% by mass or less with respect to the total mass of the polymeric piezoelectric film.

—Crystallization Accelerator (Nucleating Agent)—

A polymeric piezoelectric film of the current embodiment may contain at least one kind of crystallization accelerator (crystal nucleating agent).

Although there is no particular restriction on a crystallization accelerator (crystal nucleating agent) insofar as a crystallization accelerating effect can be recognized, it is preferable to select a substance with the crystal structure having lattice spacing close to the lattice spacing of the crystal lattice of the optically active polymer. This is because a substance having closer lattice spacing has the higher activity as a nucleating agent. For example, when the polylactic acid-type resin is used as the optically active polymer, examples include an organic substance, such as zinc phenylsulfonate, melamine polyphosphate, melamine cyanurate, zinc phenylphosphonate, calcium phenylphosphonate, and magnesium phenylphosphonate, and an inorganic substance, such as talc and clay. Among others, zinc phenylphosphonate, which has lattice spacing closest to the lattice spacing of polylactic acid and exhibits excellent crystallization accelerating activity, is preferable. Meanwhile, a commercial product can be used as a crystallization accelerator. Specific examples thereof include ECOPROMOTE (zinc phenylphosphonate: by Nissan Chemical Industries, Ltd.).

The content of a crystal nucleating agent with respect to 100 parts by mass of the optically active polymer is normally from 0.01 to 1.0 part by mass, preferably from 0.01 to 0.5 parts by mass, and from a viewpoint of better crystallization accelerating activity and maintenance of a biomass ratio especially preferably from 0.02 to 0.2 parts by mass.

When the content of a crystal nucleating agent is 0.01 parts by mass or more, the crystallization accelerating effect can be attained more effectively. When the content of a crystal nucleating agent is less than 1.0 part by mass, the crystallization speed can be regulated more easily.

From a viewpoint of transparency, the polymeric piezoelectric film preferably does not contain a component other than a helical chiral polymer having optical activity.

[Refractive Index]

In a polymeric piezoelectric film of the present embodiment, when a refractive index in a slow axis direction in the film surface is nₓ, a refractive index in a fast axis direction in the film surface is n_{y}, a refractive index in a thickness direction of the film is n_{z}, and an Nz coefficient=(nₓ−n_{z})/(nₓ−n_{y}), the Nz coefficient is from 1.108 to 1.140.

Herein, nₓ is a refractive index in a slow axis direction in the principal plane of a film at a wavelength of 589 nm, n_{y} is a refractive index in a fast axis direction in the principal plane of a film at a wavelength of 589 nm, and n_{z} is a refractive index in the thickness direction of a film at a wavelength of 589 nm.

The refractive index of a polymeric piezoelectric film may be measured by using a commercially available refractometer such as a multi-wavelength Abbe refractometer, DR-M series manufactured by ATAGO CO., LTD.

The Nz coefficient may be from 1.108 to 1.140, and is preferably from 1.109 to 1.130, and more preferably from 1.110 to 1.120.

The value of nₓ is not particularly limited as long as the above Nz coefficient can satisfy the range of from 1.108 to 1.140, and preferably from 1.4720 to 1.4760, more preferably from 1.4720 to 1.4740, and further preferably from 1.4720 to 1.4730.

The value of n_{y} is not particularly limited as long as the above Nz coefficient can satisfy the range of from 1.108 to 1.140, and preferably from 1.4500 to 1.4550, and more preferably from 1.4510 to 1.4530. The value of n_{z} is not particularly limited as long as the above Nz coefficient can satisfy the range of from 1.108 to 1.140, and preferably from 1.4450 to 1.4530, and more preferably from more than 1.4480 to less than 1.4500.

[Crystallinity]

The crystallinity of a polymeric piezoelectric film is determined by a DSC method, and the crystallinity of a polymeric piezoelectric film of the present embodiment is from 20% to 80%, and preferably from 30% to 70%, and more preferably from 35% to 60%. When the crystallinity is in the above range, a favorable balance between the piezoelectricity, the transparency, and the longitudinal tear strength of a polymeric piezoelectric film is attained, and whitening or a break is less likely to occur during stretching, and therefore, the polymeric piezoelectric film is easily manufactured.

When the crystallinity is 20% or more, the piezoelectricity of a polymeric piezoelectric film is maintained high.

When the crystallinity is 80% or less, deterioration of the longitudinal tear strength and transparency can be suppressed.

In the present embodiment, by adjusting conditions of crystallization and stretching during production of a polymeric piezoelectric film, the crystallinity of the polymeric piezoelectric film can be adjusted to from 20% to 80%.

[Standardized Molecular Orientation MORc]

The above Standardized molecular orientation MORc is a value determined based on a “degree of molecular orientation MOR” which is an index indicating the degree of orientation of a helical chiral polymer.

Here, the degree of molecular orientation MOR (Molecular Orientation Ratio) is measured by the following microwave measurement method. Namely, a polymeric piezoelectric film (sample) is placed in a microwave resonant waveguide of a well known microwave molecular orientation ratio measuring apparatus (also referred to as a “microwave transmission-type molecular orientation meter”) such that the polymeric piezoelectric film plane (film plane) is arranged perpendicular to the travelling direction of the microwaves. Then, the sample is continuously irradiated with microwaves whose oscillating direction is biased unidirectionally, while maintaining such conditions, the sample is rotated in a plane perpendicular to the travelling direction of the microwaves from 0 to 360°, and the intensity of the microwaves passed through the sample is measured to determine the molecular orientation ratio MOR.

Standardized molecular orientation MORc in the current embodiment means a MOR value to be obtained at the reference thickness tc of 50 μm, and can be determined by the following formula.

MORc=(tc/t)×(MOR−1)+1

(tc: Reference thickness corrected to; t: Sample thickness)

A standardized molecular orientation MORc can be measured by a known molecular orientation meter, such as a microwave-type molecular orientation analyzer MOA-2012A or MOA-6000 manufactured by Oji Scientific Instruments, at a resonance frequency in the vicinity of 4 GHz or 12 GHz.

The standardized molecular orientation MORc of a polymeric piezoelectric film of the present embodiment is preferably from 1.0 to 15.0, more preferably from 3.5 to 10.0, and further preferably from 4.0 to 8.0.

When the standardized molecular orientation MORc is 1.0 or more, a large number of molecular chains of the optically active polymer (for example, polylactic acid molecular chains) are aligned in the stretching direction, and as a result, a higher rate of generation of oriented crystals can be attained to exhibit higher piezoelectricity.

When the standardized molecular orientation MORc is 15.0 or less, a decrease in transparency due to an excessively large amount of molecular chains of a molecularly oriented helical chiral polymer is suppressed, and as a result, the transparency of a polymeric piezoelectric film is maintained. When the standardized molecular orientation MORc is 15.0 or less, the longitudinal tear strength can be further improved.

[Product of Standardized Molecular Orientation MORc and Crystallinity]

In the present embodiment, a product of the crystallinity and the standardized molecular orientation MORc of a polymeric piezoelectric film is from 40 to 700. When the product is adjusted within the above range, the balance between the piezoelectricity and the transparency of a polymeric piezoelectric film is favorable, and the dimensional stability is high, and deterioration of longitudinal tear strength (that is, tear strength in a certain direction) is suppressed.

The product of the standardized molecular orientation MORc and the crystallinity of a polymeric piezoelectric film is preferably from 75 to 600, more preferably from 100 to 500, further preferably from 125 to 400, and particularly preferably from 150 to 300.

It is possible to adjust the product within the above range, for example, by adjusting the conditions of crystallization and stretching when the polymeric piezoelectric film is manufactured.

The standardized molecular orientation MORc can be controlled by conditions (for example, heating temperature and heating time) of crystallization when a polymeric piezoelectric film is manufactured and conditions (for example, stretching temperature and stretching speed) of stretching.

The standardized molecular orientation MORc can be converted to birefringence Δn which is obtained by dividing retardation by a film thickness.

Specifically, the retardation can be measured by a RETS100 manufactured by Otsuka Electronics Co., Ltd. MORc and Δn are approximately in a linearly proportional relationship, and when Δn is 0, MORc is 1.

[Piezoelectric Constant d₁₄ (Stress-Electric Charge Method)]

The piezoelectricity of a polymeric piezoelectric film can be evaluated by, for example, measuring the piezoelectric constant d₁₄ of the polymeric piezoelectric film.

In the following, one example of a method of measuring the piezoelectric constant d₁₄ by a stress-electric charge method will be described.

First, a polymeric piezoelectric film is cut to a length of 150 mm in the direction of 45° with respect to the stretching direction (MD direction), and to 50 mm in the direction perpendicular to the above 45° direction, to prepare a rectangular specimen. Subsequently, the prepared specimen is set on a stage of Showa Shinku SIP-600, and aluminum (hereinafter, referred to as “Al”) is deposited on one surface of the specimen such that the deposition thickness of Al becomes about 50 nm. Subsequently, Al is deposited on the other surface of the specimen similarly. Both surfaces of the specimen are covered with Al to form conductive layers of Al.

The specimen of 150 mm×50 mm having the Al conductive layers formed on both surfaces is cut to a length of 120 mm in the direction of 450 with respect to the stretching direction (MD direction) of the polymeric piezoelectric film, and to 10 mm in the direction perpendicular to the above 45° direction, to cut out a rectangular film of 120 mm×10 mm. This film is used as a sample for measuring a piezoelectric constant.

The sample thus obtained is set in a tensile testing machine (TENSILON RTG-1250 manufactured by A&D Company, Limited) having a distance between chucks, of 70 mm so as not to be slack. A force is applied periodically at a crosshead speed of 5 mm/min such that the applied force reciprocates between 4 N and 9 N. In order to measure a charge amount generated in the sample according to the applied force at this time, a capacitor having an electrostatic capacity Qm (F) is connected in parallel to the sample, and a voltage V between the terminals of this capacitor Cm (95 nF) is measured through a buffer amplifier. The above measurement is performed under a temperature condition of 25° C. A generated charge amount Q (C) is calculated as a product of the capacitor capacity Cm and a voltage Vm between the terminals. The piezoelectric constant d₁₄ is calculated by the following formula.

d₁₄=(2×t)/L×Cm·ΔVm/ΔF
t: sample thickness (m)
L: distance between chucks (m)
Cm: capacity (F) of capacitor connected in parallel
ΔVm/ΔF: ratio of change amount of voltage between terminals of capacitor with respect to change amount of force

A higher piezoelectric constant d₁₄ results in a larger displacement of the polymeric piezoelectric film with respect to a voltage applied to the polymeric piezoelectric film, and reversely a higher voltage generated responding to a force applied to the polymeric piezoelectric film, and therefore is advantageous as a polymeric piezoelectric film.

Specifically, in the polymeric piezoelectric film according to the invention, the piezoelectric constant d₁₄ measured at 25° C. by a stress-charge method is 1 pC/N or more, preferably 3 pC/N or more, more preferably 5 pC/N or more, and further preferably 6 pC/N or more. The upper limit of the piezoelectric constant d₁₄ is not particularly limited, and is preferably 50 pC/N or less, and more preferably 30 pC/N or less, for a polymeric piezoelectric film using a helical chiral polymer from a viewpoint of a balance with transparency, or the like described below.

Similarly, from a viewpoint of the balance with transparency, the piezoelectric constant d₁₄ measured by a resonance method is preferably 15 pC/N or less.

Herein, the “MD direction” refers to a direction (Machine Direction) in which a film flows, and the “TD direction” refers to a direction (Transverse Direction) which is perpendicular to the MD direction and parallel to a principal plane of the film.

[Transparency (Internal Haze)]

Transparency of a polymeric piezoelectric film can be evaluated, for example, by visual observation or measurement of haze.

An internal haze for visible light (hereinafter, also simply referred to as “internal haze”) of the polymeric piezoelectric film of the present embodiment is preferably 40% or less, more preferably 20% or less, still more preferably 10% or less, still more preferably 5% or less, particularly preferably 2.0% or less, and most preferably 1.0% or less.

The lower the internal haze of the polymeric piezoelectric film is, the better the polymeric piezoelectric film is. From a viewpoint of the balance with the piezoelectric constant, etc. the internal haze is preferably from 0.01% to 15%, more preferably from 0.01% to 10%, further preferably from 0.1% to 5%, and particularly preferably from 0.1% to 1.0%.

In the present embodiment, the “internal haze” refers to a haze from which a haze caused by the shape of an external surface of the polymeric piezoelectric film is excluded.

The “internal haze” herein refers to a value measured with respect to a polymeric piezoelectric film at 25° C. in accordance with JIS-K7105.

More specifically, the internal haze (hereinafter, also referred to as “internal haze H1”) refers to a value measured as follows.

That is, first, for a cell having an optical path length of 10 mm filled with a silicone oil, a haze (hereinafter, also referred to as “haze H2”) in the optical path length direction was measured. Next, a polymeric piezoelectric film of the present embodiment is immersed in the silicone oil of the cell such that the optical path length direction of the cell is in parallel with the normal direction of the film, and a haze (hereinafter, also referred to as “haze H3”) in the optical path length direction of a cell in which the polymeric piezoelectric film is immersed. The haze H2 and the haze H3 are both measured at 25° C. in accordance with JIS-K7105.

An internal haze H1 is determined in accordance with the following formula based on the measured haze H2 and haze H3.

Internal haze (H1)=Haze (H3)−Haze (H2)

Measurement of the haze H2 and the haze H3 can be performed by using, for example, a haze measuring machine [TC-HIII DPK manufactured by Tokyo Denshoku Co., Ltd.,].

For the silicone oil, for example, “Shin-Etsu Silicone (trade mark), model number: KF-96-100CS” manufactured by Shin-Etsu Chemical Co., Ltd. can be used.

[Tear Strength]

The tear strength (longitudinal tear strength) of a polymeric piezoelectric film of the present embodiment is evaluated based on the tear strength measured according to the “Right angled tear method” stipulated in JIS K 7128-3 “Plastics—Tear strength of films and sheets”.

Here, the crosshead speed of a tensile testing machine is set at 200 m/min and tear strength is calculated according to the following formula:

T=F/d

wherein T stands for the tear strength (N/mm), F for the maximum tear load, and d for the thickness (mm) of a specimen.

[Dimensional Stability]

Preferably, the dimensional change rate of a polymeric piezoelectric film under heat is low, especially at a temperature of an environment where devices or apparatus described below such as a loudspeaker or a touch panel incorporating the film are used. This is because, when the dimension of a piezoelectric material changes in a service environment of a device, positions of wiring, or the like connected with the piezoelectric material are moved, which may cause malfunctioning of the device. The dimensional stability of a polymeric piezoelectric film is evaluated by a dimensional change rate before and after a heat treatment for 10 minutes at 150° C., which is a temperature slightly higher than the service environment of a device as described below. The dimensional change rate is preferably 10% or less, and more preferably 5% or less.

The thickness of a polymeric piezoelectric film of the present embodiment is not particularly restricted, and is preferably from 10 μm to 400 μm, more preferably from 20 μm to 200 μm, further preferably from 20 μm to 100 μm, and particularly preferably from 20 μm to 80 μm.

<Method of Manufacturing Polymeric Piezoelectric Film>

There is no particular restriction on a method of producing a polymeric piezoelectric film according to the invention, insofar as the crystallinity can be regulated from 20% to 80% and the product of the standardized molecular orientation MORc and the crystallinity can be regulated from 40 to 700, and the Nz coefficient can be regulated from 1.108 to 1.140.

As such a method, a method in which a sheet in an amorphous state containing the optically active polymer as described above is subjected to crystallization and stretching (either may be earlier) and the respective conditions for the crystallization and the stretching are regulated can be used.

The term “crystallization” herein is a concept including pre-crystallization described below and an annealing treatment described below.

A sheet in an amorphous state means a sheet obtained by heating a simple optically active polymer or a mixture containing the optically active polymer to a temperature equal to or above the melting point Tm of the optically active polymer and then quenching the same. The quenching temperature is for example 50° C.

In a method of producing a polymeric piezoelectric film according to the invention, the optically active polymer (polylactic acid-type polymer, etc.) may be used singly, or a mixture of two or more optically active polymers (polylactic acid-type polymers, etc.) described above or a mixture of at least one optically active polymer described above and at least one other component may be used as a raw material for a polymeric piezoelectric film (or a sheet in an amorphous state).

The mixture is preferably a mixture obtained by melt-kneading.

Specifically, when two or more optically active polymers are mixed, or at least one optically active polymer and another component (for example, the inorganic filler and the crystal nucleating agent) are mixed, optically active polymer(s) to be mixed (according to need, together with another component) are melt-kneaded in a melt-kneading machine (LABO PLASTOMILL mixer, by Toyo Seiki Seisaku-sho, Ltd.) under conditions of the mixer rotating speed of from 30 rpm to 70 rpm at from 180° C. to 250° C. for from five minutes to 20 minutes to obtain a blend of plural kinds of optically active polymers or a blend of an optically active polymer and another component such as an inorganic filler.

Embodiments of a method of producing a polymeric piezoelectric film according to the present invention will be described below, provided that a process for producing a polymeric piezoelectric film according to the present invention is not limited to the following embodiments.

A method of producing a polymeric piezoelectric film of the present embodiment includes, for example, a first step of heating a sheet in an amorphous state containing the optically active polymer (namely, a helical chiral polymer with the weight average molecular weight from 50,000 to 1,000,000 having optical activity) to obtain a pre-crystallized sheet, and a second step of stretching the pre-crystallized sheet in biaxial directions (for example, while stretching mainly in a uniaxial direction, simultaneously or successively stretched in a direction different from said stretching direction).

In a method of producing a polymeric piezoelectric film of the present embodiment, it is preferable that, in a second step, biaxially stretching is performed such that, when a stretching ratio in a direction in which the stretching ratio is large is defined as a main stretching ratio, and a stretching ratio in a direction that is perpendicular to the direction in which the stretching ratio is large and that is parallel to the film surface is defined as a secondary stretching ratio, a main stretching ratio/secondary stretching ratio is from 3.0 to 3.5.

This makes it possible to suitably manufacture a polymeric piezoelectric film, wherein a crystallinity of the film measured by a DSC method is from 20% to 80%, a product of a standardized molecular orientation MORc measured by a microwave transmission-type molecular orientation meter based on a reference thickness of 50 μm and the crystallinity is from 40 to 700, and the Nz coefficient is from 1.108 to 1.140.

Generally, by intensifying a force applied to a film during stretching, there appears tendency that the orientation of optically active polymers is promoted, and the piezoelectric constant is enhanced, meanwhile, crystallization is progressed to increase the crystal size, and consequently the internal haze also increases. Further, as a result of increase in internal stress, the dimensional change rate tends to increase. When a force is applied simply to a film, not oriented crystals, such as spherocrystals, are formed. Poorly oriented crystals such as spherocrystals increase the internal haze but hardly contribute to increase in the piezoelectric constant.

Therefore, in order to produce a film having a high piezoelectric constant and low internal haze, it is preferable to form efficiently such micro-sized orientated crystals, as contribute to the piezoelectric constant but not increase the internal haze.

From the above, for example, by producing a pre-crystallized sheet having minute crystals (crystallites) formed by pre-crystallization in a sheet prior to stretching and then stretching the pre-crystallized sheet, a force of stretching can be acted efficiently on a low-crystallinity polymer part between a crystallite and a crystallite inside the pre-crystallized sheet. By this, the optically active polymer can be oriented efficiently in a principal stretching direction.

Specifically, by stretching the pre-crystallized sheet, minute orientated crystals are formed in a low-crystallinity polymer part between a crystallite and a crystallite and at the same time spherocrystals formed by pre-crystallization are collapsed and lamellar crystals constituting the spherocrystals are aligned as tied in a row by tie-molecular chains in the stretching direction. By this, a desired MORc value can be attained.

As a result, by stretching the pre-crystallized sheet, a sheet with a low internal haze value can be obtained without compromising remarkably the piezoelectric constant. Further, by regulating the production conditions, a polymeric piezoelectric film superior in dimensional stability can be obtained.

However, according to the method of stretching a pre-crystallized sheet, since polymer chains in a low-crystallinity part inside a pre-crystallized sheet are disentangled and aligned in a stretching direction by stretching, the tear strength against a force from a direction nearly perpendicular to the stretching direction is improved, but reversely the tear strength against a force from a direction nearly parallel to the stretching direction may be deteriorated.

In view of the above, the constitution of the present embodiment includes a first step of heating a sheet in an amorphous state containing the optically active polymer to obtain a pre-crystallized sheet, and a second step of stretching the pre-crystallized sheet in biaxial directions.

In the present embodiment, when the pre-crystallized sheet is stretched in the second step (stretching step) in order to improve the piezoelectricity (also referred to as “principal stretching”), the pre-crystallized sheet is stretched simultaneously or successively in a direction crossing the stretching direction of the principal stretching (also referred to as “secondary stretching”) to perform biaxial stretching. This can align molecular chains in the sheet not only in the direction of the principal stretching axis but also in the direction crossing the principal stretching axis, and as a consequence the product of the standardized molecular orientation MORc and the crystallinity can be regulated appropriately within a certain range (specifically from 40 to 700).

As the result, while maintaining the transparency, the piezoelectricity can be enhanced, and further the longitudinal tear strength can be improved.

For the control of standardized molecular orientation MORc, it is important to regulate the heating time and the heating temperature for a sheet in an amorphous state in the first step, and the stretching speed and the stretching temperature for a pre-crystallized sheet in the second step.

As described above, the optically active polymer is a polymer having a helical molecular structure and having optical activity.

A sheet in an amorphous state containing the optically active polymer may be those commercially available, or produced by a known film forming process such as an extrusion process. A sheet in an amorphous state may have a single layer or multiple layers.

[First Step (Pre-Crystallization Step)]

The first step in the present embodiment is a step of heating a sheet in an amorphous state containing the optically active polymer to obtain a pre-crystallized sheet.

As a treatment through the first step and the second step in the present embodiment, specifically, it may be: 1) a treatment (off-line treatment) by which a sheet in an amorphous state is heat-treated to a pre-crystallized sheet (up to here the first step), and the obtained pre-crystallized sheet is set in a stretching apparatus and stretched (up to here the second step); or 2) a treatment (in-line treatment) by which a sheet in an amorphous state is set in a stretching apparatus, and heated in the stretching apparatus to a pre-crystallized sheet (up to here the first step), and the obtained pre-crystallized sheet is continuously stretched in the stretching apparatus (up to here the second step).

Although there is no particular restriction on a heating temperature T for pre-crystallizing a sheet in an amorphous state containing the optically active polymer in the first step, from viewpoints of enhancing the piezoelectricity, the transparency, or the like of a polymeric piezoelectric film produced, the heating temperature is preferably a temperature set to satisfy the following relational expression with respect to the glass transition temperature Tg of the optically active polymer, and to make the crystallinity from 1% to 70%.

Tg−40° C.≦T≦Tg+40° C.

(Tg stands for the glass transition temperature of the optically active polymer.)

The glass transition temperature Tg [° C.] of the optically active polymer and the melting point Tm [° C.] of the optically active polymer are respectively a glass transition temperature (Tg) obtained as an inflection point of a curve and a temperature (Tm) recognized as a peak value of an endothermic reaction, from a melting endothermic curve obtained for the optically active polymer using the differential scanning calorimeter (DSC) by raising the temperature under a condition of the temperature increase rate of 10° C./min.

The heat treatment time for pre-crystallization in the first step may be so regulated as to satisfy the crystallinity as desired and to make the product of the standardized molecular orientation MORc of a polymeric piezoelectric film after the stretching (after the second step) and the crystallinity of the polymeric piezoelectric film after the stretching from 40 to 700, preferably from 75 to 600, more preferably from 100 to 500, further preferably from 125 to 400, and particularly preferably from 150 to 300. When the heat treatment time becomes longer, the crystallinity after the stretching becomes higher and the standardized molecular orientation MORc after the stretching becomes also higher. When the heat treatment time becomes shorter, the crystallinity after the stretching becomes also lower and the standardized molecular orientation MORc after the stretching becomes also lower.

When the crystallinity of a pre-crystallized sheet before stretching becomes high, conceivably the sheet becomes stiff and a larger stretching stress is exerted on the sheet, and therefore such parts of the sheet, where the crystallinity is relatively low, are also orientated highly to enhance also the standardized molecular orientation MORc after stretching. Reversely, conceivably, when the crystallinity of a pre-crystallized sheet before stretching becomes low, the sheet becomes soft and a stretching stress is exerted to a lesser extent on the sheet, and therefore such parts of the sheet, where the crystallinity is relatively low, are also orientated weakly to lower also the standardized molecular orientation MORc after stretching.

The heat treatment time varies depending on the heat treatment temperature, the sheet thickness, the molecular weight of a resin constituting a sheet, and the kind and quantity of an additive. When a sheet in an amorphous state is preheated at a temperature allowing the sheet to crystallize on the occasion of preheating which may be carried out before a stretching step (second step) described below, the actual heat treatment time for crystallizing the sheet corresponds to the sum of the above preheating time and the heat treatment time at the pre-crystallization step before the preheating.

The heat treatment time for a sheet in an amorphous state is preferably from five seconds to 60 minutes, and from a viewpoint of stabilization of production conditions more preferably from one minute to 30 minutes. When, for example, a sheet in an amorphous state containing a polylactic acid resin as the optically active polymer is pre-crystallized, heating at from 20° C. to 170° C. for from five seconds to 60 minutes (preferably from one minute to 30 minutes) is preferable.

In the present embodiment, for imparting efficiently piezoelectricity, transparency, and longitudinal tear strength to a sheet after stretching, it is preferable to adjust the crystallinity of a pre-crystallized sheet before stretching.

The reason behind the improvement of the piezoelectricity or the like by stretching is believed to be because stress by stretching is concentrated on parts of a pre-crystallized sheet where the crystallinity is relatively high, which are presumably in a state of spherocrystal, such that spherocrystals are destroyed and aligned to enhance the piezoelectricity (piezoelectric constant d₁₄); and because, at the same time, the stretching stress is also exerted on parts where the crystallinity is relatively low through the spherocrystals, such that an orientation of the low crystallinity parts is promoted to enhance the piezoelectricity (piezoelectric constant d₁₄).

The crystallinity of a sheet after stretching is set to aim at from 20% to 80%, preferably at from 30% to 70%, and more preferably at from 35% to 60%. Consequently, the crystallinity of a pre-crystallized sheet just before stretching is set at 1% to 70%, preferably at 2% to 60%. The crystallinity of a pre-crystallized sheet may be carried out similarly as the measurement of the crystallinity of a polymeric piezoelectric film of the current embodiment after stretching.

The thickness of a pre-crystallized sheet is selected mainly according to an intended thickness of a polymeric piezoelectric film to be attained by means of stretching at the second step and the stretching ratio, and is preferably from 50 μm to 1000 μm, and more preferably about from 200 μm to 800 μm.

[Second Step (Stretching Process)]

There is no particular restriction on a stretching method at the second step (stretching step), a process combining stretching for forming oriented crystals (also called as principal stretching) and stretching conducted in a direction crossing the former stretching direction. By stretching a polymeric piezoelectric film, a polymeric piezoelectric film having a large area principal plane can be also obtained.

As for the principal plane area in the present embodiment, the principal plane area of a polymeric piezoelectric film is preferably 5 mm² or more, and more preferably 10 mm² or more.

It is presumed that molecular chains of a polylactic acid-type polymer contained in a polymeric piezoelectric film can be orientated uniaxially and aligned densely to attain higher piezoelectricity, if a polymeric piezoelectric film is stretched mainly uniaxially.

Meanwhile, as described above, if stretched only in one direction, polymer molecular chains in a sheet are aligned mainly in the stretching direction, and therefore the longitudinal tear strength against a force from a direction nearly perpendicular to the stretching direction may deteriorate.

When stretching for increasing the piezoelectricity (also referred to as “principal stretching”) is conducted at the stretching step, by stretching a pre-crystallized sheet simultaneously or successively in a direction crossing the stretching direction of the principal stretching (also referred to as “secondary stretching”) for performing biaxial stretching, a polymeric piezoelectric film enjoying excellent balance of piezoelectricity, transparency, and longitudinal tear strength can be obtained.

Herein, “successive stretching” means a stretching method, by which a sheet is first stretched in a uniaxial direction, and then stretched in a direction crossing the first stretching direction.

There is no particular restriction on a process for biaxial stretching in the second step, and a usual process can be applied. Specifically, a combined process of a roll stretching (stretching in the MD direction) and a tenter stretching (stretching in the TD direction) is preferable. In this case, from a viewpoint of production efficiency, the TD direction is preferably selected for the direction with a higher stretching ratio (for example, principal stretching direction), and the MD direction is preferably selected for the direction with a lower stretching ratio (for example, secondary stretching direction).

The biaxial stretching may be conducted simultaneously or successively.

In a case of successive stretching, from a viewpoint of suppression of the longitudinal tearing of film during the second or later stretching, the ratio of the first stretching is preferably large, and from a viewpoint of suppressing decrease in a piezoelectric constant, the ratio of the first stretching is preferably small.

As described above, “MD direction” means the flow direction of a film, and “TD direction” means a direction perpendicular to the MD direction and parallel to the principal plane of the film.

Although there is no particular restriction on the stretching ratio, insofar as the crystallinity of a polymeric piezoelectric film and the product of the MORc and the crystallinity after the stretching (or after the annealing treatment, when the annealing step described below is performed) can be regulated within the above described range, the stretching ratio of the main stretching is preferably from 2-fold to 8-fold, more preferably from 3-fold to 5-fold, and further preferably from 3.5-fold to 4.5-fold. The stretching ratio of the secondary stretching is more preferably from 1.1-fold to 1.4-fold, and further preferably from 1.1-fold to 1.3-fold.

The stretching ratio of the main stretching to the stretching ratio of the secondary stretching (main stretching ratio/secondary stretching ratio) is preferably from 3.0 to 3.5, and more preferably from 3.1 to 3.5.

The product of the main stretching ratio and the secondary stretching ratio is preferably from 4.6 to 5.6, more preferably from 4.6 to 5.3, and further preferably from 4.6 to 5.0.

There is also no particular restriction on the stretching speed, and usually the principal stretching speed and the secondary stretching speed are regulated according to the ratio. The stretching speed may be set at a usually applied speed without particular restriction, and is often regulated to a speed which does not cause breakage of a film during the stretching.

When a polymeric piezoelectric film is stretched solely by a tensile force as in the cases of a biaxial stretching method, the stretching temperature of a polymeric piezoelectric film is preferably in a range of 10° C. to 20° C. higher than the glass transition temperature of a polymeric piezoelectric film.

When a pre-crystallized sheet is stretched, the sheet may be preheated immediately before stretching so that the sheet can be easily stretched.

Since the preheating is performed generally for the purpose of softening the sheet before stretching in order to facilitate the stretching, the same is normally performed avoiding conditions that promote crystallization of a sheet before stretching and make the sheet stiff.

Meanwhile, as described above, in the present embodiment pre-crystallization is performed before stretching, and therefore the preheating may be performed combined with the pre-crystallization. Specifically, by conducting the preheating at a higher temperature than a temperature normally used, or for longer time conforming to the heating temperature or the heat treatment time at the aforementioned pre-crystallized step, preheating and pre-crystallization can be combined.

[Annealing Treatment Step]

From a viewpoint of improvement of the piezoelectric constant, a polymeric piezoelectric film after a stretching treatment should preferably be subjected to a certain heat treatment (hereinafter also referred to as an “annealing treatment”). The temperature of an annealing treatment is preferably about from 80° C. to 160° C. and more preferably from 100° C. to 155° C.

There is no particular restriction on a method of applying a high temperature in an annealing treatment, and examples thereof include a direct heating method using a hot air heater or an infrared heater, and a method, for dipping a polymeric piezoelectric film in a heated liquid such as silicone oil. In this case, when a polymeric piezoelectric film is deformed by linear expansion, it becomes practically difficult to obtain a flat film, and therefore high temperature is applied preferably under application of a certain tensile stress (e.g. 0.01 MPa to 100 MPa) on a polymeric piezoelectric film to prevent the polymeric piezoelectric film from sagging.

The high temperature application time at an annealing treatment is preferably from one second to 60 minutes, more preferably from one second to 300 seconds, and further preferably, heating is performed for from one second to 60 seconds. By annealing for 60 minutes or less, decrease in the degree of orientation due to growth of spherocrystals from molecular chains in an amorphous part at a temperature above the glass transition temperature of a polymeric piezoelectric film can be suppressed, and as a result, deterioration of the piezoelectricity can be suppressed.

A polymeric piezoelectric film treated for annealing as described above is preferably quenched after the annealing treatment.

In connection with an annealing treatment, “quench” means that a polymeric piezoelectric film treated for annealing is dipped, for example, in ice water immediately after the annealing treatment and chilled at least to the glass transition temperature Tg or lower, and between the annealing treatment and the dipping in ice water, or the like, there is no other treatment.

Examples of a quenching method include a dipping method, by which a polymeric piezoelectric film treated for annealing is dipped in a cooling medium, such as water, ice water, ethanol, ethanol or methanol containing dry ice, and liquid nitrogen; a cooling method, by which a liquid with the low vapor pressure is sprayed for chilling by evaporation latent heat thereof.

For chilling continuously a polymeric piezoelectric film, quenching by contacting a polymeric piezoelectric film with a metal roll regulated at a temperature below the glass transition temperature Tg of the polymeric piezoelectric film is possible. The number of quenches may be once or two times or more; or annealing and quenching can be repeated alternately. When a polymeric piezoelectric film having received the stretching treatment is subjected to the annealing, the polymeric piezoelectric film may be shrunk after the annealing compared to before the annealing.

<Use of Polymeric Piezoelectric Film>

A polymeric piezoelectric film of the invention can be used in a variety of fields including a loudspeaker, a headphone, a touch panel, a remote controller, a microphone, a hydrophone, an ultrasonic transducer, an ultrasonic applied measurement instrument, a piezoelectric vibrator, a mechanical filter, a piezoelectric transformer, a delay unit, a sensor, an acceleration sensor, an impact sensor, a vibration sensor, a pressure-sensitive sensor, a tactile sensor, an electric field sensor, a sound pressure sensor, a display, a fan, a pump, a variable-focus mirror, a sound insulation material, a soundproof material, a keyboard, acoustic equipment, information processing equipment, measurement equipment, and a medical appliance, and from a viewpoint that a high sensor sensitivity can be maintained when the film is used for a device, a polymer film of the invention is preferably utilized particularly in a field of variety of sensors.

A polymeric piezoelectric film of the invention can also be used as a touch panel formed by combining the polymeric piezoelectric film with a display device. For the display device, for example, a liquid crystal panel, an organic EL panel, or the like can also be used.

A polymeric piezoelectric film of the invention can also be used as a pressure-sensitive sensor, by combining the polymeric piezoelectric film with another type touch panel (position detecting member). Examples of the detection method of the position detecting member include an anti-film method, an electrostatic capacitance method, a surface acoustic wave method, an infrared method, and an optical method.

In this case, a polymeric piezoelectric film according to the present invention is preferably used as a piezoelectric element having at least two planes provided with electrodes. It is enough if the electrodes are provided on at least two planes of the polymeric piezoelectric film. There is no particular restriction on the electrode, and examples thereof to be used include ITO, ZnO, IZO (registered trade marks), IGZO, an electroconductive polymer, silver nanowire, and metal mesh.

A polymeric piezoelectric film according to the present invention and an electrode may be piled up one another and used as a layered piezoelectric element. For example, units of an electrode and a polymeric piezoelectric film are piled up recurrently and finally a principal plane of a polymeric piezoelectric film not covered by an electrode is covered by an electrode. Specifically, that with two recurrent units is a layered piezoelectric element having an electrode, a polymeric piezoelectric film, an electrode, a polymeric piezoelectric film, and an electrode in the mentioned order. With respect to a polymeric piezoelectric film to be used for a layered piezoelectric element, at least one layer of polymeric piezoelectric film is required to be made of a polymeric piezoelectric film according to the present invention, and other layers may not be made of a polymeric piezoelectric film according to the present invention.

In the case that plural polymeric piezoelectric films according to the present invention are included in a layered piezoelectric element, when an optically active polymer contained in a polymeric piezoelectric film according to the present invention in a layer has L-form optical activity, an optically active polymer contained in a polymeric piezoelectric film in another layer may be either of L-form and D-form. The location of polymeric piezoelectric films may be adjusted appropriately according to an end use of a piezoelectric element.

For example, when the first layer of a polymeric piezoelectric film containing as a main component an L-form optically active polymer is laminated intercalating an electrode with the second polymeric piezoelectric film containing as a main component an L-form optically active polymer, the uniaxial stretching direction (principal stretching direction) of the first polymeric piezoelectric film should preferably cross, especially perpendicularly cross, the uniaxial stretching direction (principal stretching direction) of the second polymeric piezoelectric film so that the displacement directions of the first polymeric piezoelectric film and the second polymeric piezoelectric film can be aligned, and that the piezoelectricity of a laminated piezoelectric element as a whole can be favorably enhanced.

On the other hand, when the first layer of a polymeric piezoelectric film containing as a main component an L-form optically active polymer is laminated intercalating an electrode with the second polymeric piezoelectric film containing as a main component an D-form optically active polymer, the uniaxial stretching direction (principal stretching direction) of the first polymeric piezoelectric film should preferably be arranged nearly parallel to the uniaxial stretching direction (principal stretching direction) of the second polymeric piezoelectric film so that the displacement directions of the first polymeric piezoelectric film and the second polymeric piezoelectric film can be aligned, and that the piezoelectricity of a laminated piezoelectric element as a whole can be favorably enhanced.

Especially, when a principal plane of a polymeric piezoelectric film is provided with an electrode, it is preferable to provide a transparent electrode. In this regard, a transparent electrode means specifically that its internal haze is 40% or less (total luminous transmittance is 60% or more).

The piezoelectric element using a polymeric piezoelectric film of the invention may be applied to the aforementioned various piezoelectric devices including a loudspeaker and a touch panel. A piezoelectric element provided with a transparent electrode is favorable for applications, such as a loudspeaker, a touch panel, and an actuator.

### EXAMPLES

The embodiment of the present invention will be described below in more details by way of Examples, provided that the current embodiment is not limited to the following Examples to the extent not to depart from the spirit of the embodiment.

### Example 1

A polylactic acid resin (product name: Ingeo™ biopolymer, brand: 4032D) manufactured by NatureWorks LLC was charged into an extruder hopper, heated to from 220° C. to 230° C., extruded through a T-die, and contacted with a cast roll at 50° C. for 0.3 minutes to form a 210 μm-thick pre-crystallized sheet (pre-crystallization step). The crystallinity of the pre-crystallized sheet was measured to find 4%.

The obtained pre-crystallized sheet was subjected to sequential biaxial stretching to obtain a stretched film (stretching step). Specifically, the pre-crystallized sheet was stretched with heating at 70° C. to 1.2-fold in the MD direction by a roll-to-roll method (secondary stretching), and then stretched with heating at 75° C. to 4.0-fold in the TD direction by a tenter method (main stretching) to obtain a stretched film. In this case, the width of the pre-crystallized sheet was 1,500 mm, and the feed speed of the pre-crystallized sheet was 5 m/minute.

The film after the stretching step was allowed to pass through a furnace heated to 150° C. for 15 seconds while being fixed with a tenter to perform an annealing treatment, and quenched to produce a polymeric piezoelectric film (annealing treatment step). The quenching was performed by contacting the film, after the annealing treatment, with air at from 20° C. to 30° C., and further contacting the film with metallic rolls of a film winding machine to rapidly lower the film temperature to close to room temperature.

Physical properties of polylactic acid resins used in Example 1 and the following Example 2, and Comparative Examples 1 and 2 are as listed on Table 1 below.

TABLE 1
Polylactic acid resin

| | | | | Optical purity |
|---|---|---|---|---|
| Resin | Chirality | Mw | Mw/Mn | (% ee) |
| LA | L | 200,000 | 1.87 | 97.0 |

### Example 2

A polymeric piezoelectric film of Example 2 was produced in the same manner as Example 1 except that the stretching conditions were changed to the conditions listed on Table 2 below in the production of a polymeric piezoelectric film of Example 1.

### Comparative Examples 1 and 2

Subsequently, polymeric piezoelectric films of Comparative Examples 1 and 2 were produced in the same manner as Example 1 except that the stretching conditions were changed to the conditions listed on Table 2 below in the production of a polymeric piezoelectric film of Example 1.

TABLE 2

| | Stretching condition | | | | |
|---|---|---|---|---|---|
| | | | | | Total |
| | | Magni- | Magni- | | magni- |
| | | fication | fication | | fication |
| | Method | (MD) | (TD) | TD/MD | TD × MD |
| Example 1 | Sequential | 1.2 | 4.0 | 3.3 | 4.8 |
| | biaxial | | | | |
| | stretching | | | | |
| Example 2 | Sequential | 1.3 | 4.0 | 3.1 | 5.2 |
| | biaxial | | | | |
| | stretching | | | | |
| Comparative | Sequential | 1.0 | 4.0 | 4.0 | 4.0 |
| Example1 | biaxial | | | | |
| | stretching | | | | |
| Comparative | Sequential | 1.5 | 4.0 | 2.7 | 6.0 |
| Example2 | biaxial | | | | |
| | stretching | | | | |

—Measurement of Amounts of L-Form and D-Form of Resin (Optically Active Polymer)—

Into a 50 mL Erlenmeyer flask, 1.0 g of a weighed-out sample (polymeric piezoelectric film) was charged, to which 2.5 mL of IPA (isopropyl alcohol) and 5 mL of a 5.0 mol/L sodium hydroxide solution were added. The Erlenmeyer flask containing the sample solution was then placed in a water bath at the temperature of 40° C., and stirred until polylactic acid was completely hydrolyzed for about 5 hours.

After the sample solution was cooled down to room temperature, 20 mL of a 1.0 mol/L hydrochloric acid solution was added for neutralization, and the Erlenmeyer flask was stoppered tightly and stirred well. The sample solution (1.0 mL) was dispensed into a 25 mL measuring flask and diluted to 25 mL with a mobile phase to prepare a HPLC sample solution 1. Into an HPLC apparatus 5 μL of the HPLC sample solution 1 was injected, and D/L-form peak areas of polylactic acid were determined under the following HPLC conditions. The amounts of L-form and D-form were calculated therefrom.

### —HPLC Measurement Conditions—

### Column:

Optical resolution column, SUMICHIRAL OA5000 (manufactured by Sumika Chemical Analysis Service, Ltd.)

Measuring apparatus:

Liquid chromatography (manufactured by Jasco Corporation)

Column temperature:

25° C.

Mobile phase:

1.0 mM-copper (II) sulfate buffer solution/IPA=98/2 (V/V)
Copper (TI) sulfate/IPA/water=156.4 mg/20 mL/980 mL
   Mobile phase flow rate:

1.0 mL/min

### Detector:

Ultraviolet detector (UV 254 nm)

<Molecular Weight Distribution>

The molecular weight distribution (Mw/Mn) of a resin (optically active polymer) contained in each polymeric piezoelectric film of Examples and Comparative Examples was measured using a gel permeation chromatograph (GPC) by the following GPC measuring method.

### —GPC Measuring Method—

Measuring apparatus:

GPC-100 (manufactured by Waters) Column:

SHODEX LF-804 (manufactured by Showa Denko K.K.)

Preparation of sample:

Each polymeric piezoelectric film of Examples and Comparative Examples was dissolved in a solvent (chloroform) at 40° C. to prepare a sample solution with the concentration of 1 mg/mL.

Measuring conditions:

0.1 mL of a sample solution was introduced into the column at a temperature of 40° C. and a flow rate of 1 mL/min by using chloroform as a solvent, and the concentration of the sample that was contained in the sample solution and separated by the column was measured by a differential refractometer. With respect to the molecular weight of a resin, a universal calibration curve was prepared using polystyrene standard samples, and the weight average molecular weight (Mw) for each resin was calculated therefrom.

<Measurement of Physical Properties and Evaluation>

With respect to each polymeric piezoelectric film of Examples 1 and 2, and Comparative Examples 1 and 2 obtained as above, the melting point Tm, crystallinity, thickness, internal haze, piezoelectric constant, MORc, dimensional change rate, tear strength, and elongation at break were measured.

The evaluation results are shown in Table 3.

The measurements were carried out specifically as follows

[Melting Point Tm and Crystallinity]

Each 10 mg of respective polymeric piezoelectric films of Examples and Comparative Examples was weighed accurately and measured by a differential scanning calorimeter (DSC-1, manufactured by Perkin Elmer Inc.) at a temperature increase rate of 10° C./min to obtain a melting endothermic curve. From the obtained melting endothermic curve the melting point Tm, and crystallinity were obtained.

[Dimensional Change Rate]

Each polymeric piezoelectric film of Examples and Comparative Examples was cut to a length of 50 mm in the MD direction and to 50 mm in the TD direction, to cut out a piece of 50 mm×50 mm rectangular film. The film was hanged in an oven set at 100° C. and subjected to an annealing treatment for 30 minutes (the annealing treatment for evaluation of the dimensional change rate is hereinafter referred to as “annealing B”). During that procedure the lengths of the film rectangle sides in the MD direction and in the TD direction before and after the annealing B was measured by a two-dimensional measurer, CRYSTAL μV606 manufactured by Mitutoyo Corporation, and the dimensional change rate (%) was calculated according to the following expression. From the absolute value of the dimensional change rate the dimensional stability was evaluated. When the dimensional change rate is lower, it means the dimensional stability is the higher.

MD dimensional change rate (%)=100×[(side length in the MD direction before annealing B)−(side length in the MD direction after annealing B)]/(side length in the MD direction before annealing B)

TD dimensional change rate (%)=100×[(side length in the TD direction before annealing B)−(side length in the TD direction after annealing B)]/(side length in the TD direction before annealing B)

[Internal Haze]

“Internal haze” means herein the internal haze of a polymeric piezoelectric film according to the present invention, and measured by the following method.

Specifically, the internal haze (hereinafter also referred to as “internal haze (H1)”) of each polymeric piezoelectric film of Examples and Comparative Examples was measured by measuring the light transmittance in the thickness direction. More precisely, the haze (H2) was measured by placing in advance only a silicone oil (Shin-Etsu Silicone (trade mark), grade: KF96-100CS; by Shin-Etsu Chemical Co., Ltd.) between 2 glass plates; then the haze (H3) was measured by placing a film (polymeric piezoelectric film), whose surfaces were wetted uniformly with the silicone oil, between two glass plates; and finally the internal haze (H1) of each polymeric piezoelectric film of Examples and Comparative Examples was obtained by calculating the difference between the above two according to the following formula:

Internal haze (H1)=haze (H3)−haze (H2)

The haze (H2) and haze (H3) in the above formula were determined by measuring the light transmittance in the thickness direction using the following apparatus under the following measuring conditions.

Measuring apparatus: HAZE METER TC-HIIIDPK (by Tokyo Denshoku Co., Ltd.)

Sample size: Width 30 mm×length 30 mm, (see Table 3 for the thickness)

Measuring conditions: According to JIS-K7105

Measuring temperature: Room temperature (25° C.)

[Piezoelectric Constant d₁₄ (Stress-Electric Charge Method)]

In accordance with “one example of a method of measuring the piezoelectric constant d₁₄ by a stress-electric charge method” described above, the piezoelectric constant (particularly, piezoelectric constant d₁₄ (stress-electric charge method)) of a crystallized polymer film was measured.

[Standardized Molecular Orientation MORc]

Standardized molecular orientation MORc was measured for each of polymeric piezoelectric films of Examples and Comparative Examples by a microwave molecular orientation meter MOA-6000 by Oji Scientific Instruments. The reference thickness tc was set at 50 μm.

[Tear Strength]

With respect to each of polymeric piezoelectric materials of Examples and Comparative Examples, the tear strength in the TD direction (longitudinal tear strength) was measured according to the “Right angled tear method” stipulated in JIS K 7128-3 “Plastics—Tear strength of films and sheets”.

When the tear strength in the TD direction is high, it means that deterioration of the longitudinal tear strength is suppressed. In other words, when at least one of the tear strength in the MD direction and the tear strength in the TD direction is low, it means that the longitudinal tear strength is deteriorated.

In the measurement of the tear strength, the crosshead speed of a tensile testing machine was set at 200 mm/min and the tear strength was calculated according to the following formula:

T=F/d

wherein T stands for the tear strength (N/mm), F for the maximum tear load, and d for the thickness (mm) of a specimen.

[Modulus of Elasticity, Yield Stress, and Elongation at Break]

For a rectangular specimen obtained by cutting each polymeric piezoelectric film of Examples and Comparative Examples to 180 mm in a direction of 45° with respect to the stretching direction (MD direction) and to 10 mm in a direction perpendicular to the above 45° direction, the modulus of elasticity, yield stress, and elongation at break in the 45° direction were measured by using a tensile testing machine STROGRAPH VD1E manufactured by Toyo Seiki Seisaku-Sho, Ltd. in accordance with JIS-K-7127.

TABLE 3

| | | | | | | | | MD | TD | | Elon- |
|---|---|---|---|---|---|---|---|---|---|---|---|
| | | | | | In- | Piezo- | | dimen- | dimen- | | gation |
| | | Crystal- | Thick- | MORc | ternal | electric | MORc × | sional | sional | Tear | at |
| | Tm | linity | ness | @50 | haze | constant | Crystal- | change | change | strength | break |
| | (° C.) | (%) | (μm) | μm | (%) | (pC/N) | linity | rate | rate | (N/mm) | (%) |
| Example 1 | 166.9 | 43.1 | 51.5 | 4.41 | 0.21 | 6.4 | 190 | 0.78 | −0.35 | 267 | 46 |
| Example 2 | 166.3 | 42.1 | 49.8 | 4.27 | 0.25 | 6.3 | 180 | 0.78 | −0.34 | 264 | 53 |
| Comparative | 167.7 | 42.2 | 50.7 | 5.85 | 0.18 | 6.7 | 247 | 0.63 | −0.35 | 112 | 3 |
| Example 1 | | | | | | | | | | | |
| Comparative | 167.4 | 42.7 | 54.1 | 4.09 | 0.2 | 5.8 | 175 | 0.77 | −0.35 | 272 | 97 |
| Example 2 | | | | | | | | | | | |

As listed on Table 3, the longitudinal tear strength and elongation at break in Examples 1 and 2 were higher than those in Comparative Example 1.

Piezoelectric constant in Examples 1 and 2 was higher than that in Comparative Example 2.

[Refractive Index]

With respect to the obtained polymeric piezoelectric films, refractive indices nₓ, n_{y}, and n_{z} at 23° C. were measured by using a multi-wavelength Abbe refractometer, DR-M2 manufactured by ATAGO CO., LTD. The Nz coefficient was then calculated based on the following formula.

Nz coefficient=(nₓ−n_{z})/(nₓ−n_{y})

nₓ is a refractive index in a slow axis direction in the principal plane of a film at a wavelength of 589 nm, n_{y} is a refractive index in a fast axis direction in the principal plane of a film at a wavelength of 589 nm, and n_{z} is a refractive index in the thickness direction of a film at a wavelength of 589 nm.

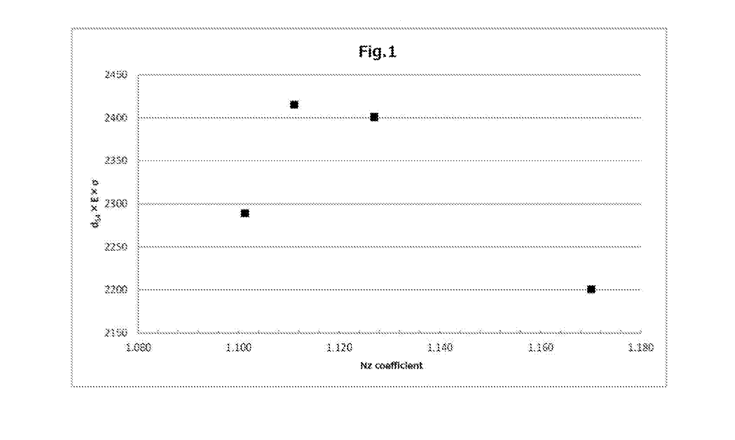

Results of parameters (piezoelectric constant d₁₄, modulus of elasticity E, yield stress σ, d₁₄×E×σ) related to refractive index and sensor sensitivity determined as above are listed on Table 4 below. The relationship between the Nz coefficient and the d₁₄×E×σ is listed on FIG. 1.

TABLE 4

| | | | | | Parameter related to sensor sensitivity | | | |
|---|---|---|---|---|---|---|---|---|
| | | | | | | Modulus | Yield | |
| | Refractive index | | | | Piezoelectric | of | stress | d₁₄ × |
| | | | | Nz | constant d₁₄ | elasticity | δ | E × |
| | nₓ | n_{y} | n_{z} | coefficient | [pC/N] | E [GPa] | [MPa] | δ |
| Example 1 | 1.4727 | 1.4520 | 1.4497 | 1.111 | 6.4 | 3.84 | 98.2 | 2413 |
| Example 2 | 1.4728 | 1.4524 | 1.4498 | 1.127 | 6.3 | 3.83 | 99.5 | 2401 |
| Comparative | 1.4730 | 1.4503 | 1.4480 | 1.101 | 6.7 | 3.77 | 90.7 | 2291 |
| Example 1 | | | | | | | | |
| Comparative | 1.4727 | 1.4533 | 1.4500 | 1.170 | 5.8 | 3.91 | 97.1 | 2202 |
| Example 2 | | | | | | | | |

Since, as listed on Tables 2 and 4, longitudinal (MD) magnification in Comparative Example 1 is lower than that in Examples 1 and 2, the value of piezoelectric constant d₁₄ is large, and the values of modulus of elasticity E and yield stress σ are small. Further, since longitudinal (MD) magnification in Comparative Example 2 is higher than those in Examples 1 and 2, surface distribution of orientation deteriorates, the value of the piezoelectric constant d₁₄ is small, and the values of modulus of elasticity E and yield stress σ are large. In Examples 1 and 2, values of the piezoelectric constant d₁₄, modulus of elasticity E and yield stress σ can be made large, and the value of d₁₄×E×σ which is a parameter for overall sensor sensitivity can be maintained large.

In other words, in Examples 1 and 2 in which the Nz coefficient is from 1.108 to 1.140, the value of d₁₄×E×σ can be made high as compared with Comparative Examples 1 and 2. Further, in Examples 1 and 2, the piezoelectric constant can be maintained high as compared with Comparative Example 2. Accordingly, in the polymeric piezoelectric films of Examples 1 and 2, the sensor sensitivity when used for a device is expected to be maintained high.

Further, as listed on Table 3, since the value of the longitudinal tear strength in Comparative Example 1 is low, a line breakage during production is likely to occur and the productivity is considered to be low. Meanwhile, in Examples 1 and 2, the value of the longitudinal tear strength is high, a line breakage during production is less likely to occur and the productivity is considered to be excellent.

The entire disclosure of Japanese Patent Applications No. 2014-218539 filed on Oct. 27, 2014 is incorporated herein by reference.

All publications, patent applications, and technical standards described in this specification are herein incorporated by reference to the same extent as if each individual publication, patent application, or technical standard was specifically and individually indicated to be incorporated by reference.

1. A polymeric piezoelectric film comprising a helical chiral polymer having a weight average molecular weight of from 50,000 to 1,000,000 and having optical activity, wherein
a crystallinity of the film measured by a DSC method is from 20% to 80%,
a product of the crystallinity and a standardized molecular orientation MORc measured by a microwave transmission-type molecular orientation meter based on a reference thickness of 50 μm is from 40 to 700, and
when a refractive Index in a slow axis direction in the film surface is nₓ, a refractive Index in a fast axis direction in the film surface is n_{y}, a refractive index in a thickness direction of the film is n_{z}, and an Nz coefficient=(nₓ−n_{z})/(nₓ−n_{y}), the Nz coefficient is from 1.108 to 1.140.

2. The polymeric piezoelectric film according to claim 1, wherein an internal haze with respect to visible light is 40% or less, and a piezoelectric constant d₁₄ measured by a stress-electric charge method at 25° C. is 1 pC/N or more.

3. The polymeric piezoelectric film according to claim 1, wherein an internal haze with respect to visible light is 20% or less.

4. The polymeric piezoelectric film according to claim 1, wherein the helical chiral polymer is a polymer having a main chain comprising a repeating unit represented by the following formula (1):

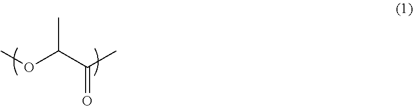

5. The polymeric piezoelectric film according to claim 1, wherein an optical purity of the helical chiral polymer is 95.00% ee or more.

6. The polymeric piezoelectric film according to claim 1, wherein a content of the helical chiral polymer is 80% by mass or more.

7. The polymeric piezoelectric film according to claim 1, wherein the refractive index nₓ in the slow axis direction in the film surface is from 1.4720 to 1.4740.

8. The polymeric piezoelectric film according to claim 1, wherein a piezoelectric constant measured by a stress-electric charge method is 6 pC/N or more.

9. The polymeric piezoelectric film according to claim 1, wherein the Nz coefficient is from 1.109 to 1.130.

10. The polymeric piezoelectric film according to claim 1, wherein an internal haze with respect to visible light is 1% or less.

11. The polymeric piezoelectric film according to claim 1, wherein the film is a biaxially stretched film, and wherein, when a stretching ratio in a direction in which the stretching ratio is large is defined as a main stretching ratio, and a stretching ratio in a direction which is perpendicular to the direction in which the stretching ratio is large and which is parallel to the film surface is defined as a secondary stretching ratio, a main stretching ratio/secondary stretching ratio is from 3.0 to 3.5.

12. The polymeric piezoelectric film according to claim 11, wherein a product of the main stretching ratio and the secondary stretching ratio is from 4.6 to 5.6.
